(19) United States
(12) Patent Application Publication
(10) Pub. No.: US 2003/0087506 A1
(43) Pub. Date: May 8, 2003

(54) Method of filling substrate depressions with silicon oxide by high-density-plasma vapor phase deposition with participation of H2O2 or H2O as reaction gas

(76) Inventor: Markus Kirchhoff, Ottendorf-Okrilla (DE)

Correspondence Address: LERNER AND GREENBERG, P.A., Post Office Box 2480, Hollywood, FL, 33022-2480, US

(21) Appl. No.: 10/289,117

(22) Filed: Nov. 6, 2002

(30) Foreign Application Priority Data
Nov. 6, 2001 (DE) 101 54 346.8

(51) Int. Cl. H01L 21/76

(52) U.S. Cl. 438/424; 438/435; 438/436

(57) ABSTRACT

A first silicon-containing reaction gas and an oxygen precursor representing a further reaction gas are fed to the reaction chamber and a high-density plasma, preferably above 10¹⁶ ions/m³, is produced. Through at least partial substitution of the precursor O₂ that is normally used, H₂O₂ and/or H₂O are fed to the reaction chamber in order to further reduce the sputtering effects due to O₂ ions during the deposition, which lead to undesirable redepositions of the SiO₂ on side walls of the depression.

### BACKGROUND OF THE INVENTION

Field of the Invention

The invention relates to a method for filling a depression contained in a substrate with silicon oxide (SiO₂). During the process, a first silicon-containing reaction gas and one or more further reaction gases are fed to a reaction chamber containing the substrate, and a chemical vapor deposition is carried out in an HDP process.

During the fabrication of semiconductor (DRAM) memory cells having a trench capacitor and a selection transistor, the trench capacitor, on one side, is electrically conductively connected to the selection transistor with a buried strap and an insulation region (STI, shallow trench isolation) is produced on the other side of the trench capacitor. The insulation region insulates the trench capacitor electrically from an adjacent memory cell. The STI insulation region is produced by a patterning step wherein a surface section formed by a partial section of the previously produced trench capacitor is removed. After the removal of this surface section, the resulting depression is filled by an insulator, generally silicon dioxide (SiO₂).

With regard to the production of STI insulation regions during the fabrication of the above-mentioned memory cells, reference is had, by way of example, to the commonly assigned, copending published patent applications US 20020137278 A1 (German DE 199 41 148 A1) and US 20020125521 A1 (German DE 199 44 012 A1).

The continual miniaturization of microelectronic and microtechnical components has the consequence that trenches and depressions with ever larger aspect ratios (=depth/diameter) occur in the fabrication process of said components. Aspect ratios of up to 3.5 have already been reached at the present time in the case of the above-mentioned STI insulation regions. In future memory cells the STI insulation region will only have a width of less than 100 nm and an aspect ratio of greater than 4, at most up to 8. However, such depressions can no longer be filled in a manner free from voids with present-day deposition methods. Voids or inclusions arise because SiO₂ material is deposited not only on the bottom of the depression but equally on the side walls thereof. This can have the effect that, on account of the high aspect ratio, the SiO₂ deposited on the side walls grows together before the depression is filled from its bottom. During later planar etching-back, for instance by means of a CMP process, these voids can then be uncovered at the surface and be filled with polycrystalline silicon in an undesirable manner during the subsequent formation of the gate of the selection transistor, as a result of which short circuits can arise.

It is known, during the deposition of SiO₂ in an HDP-CVD process, to introduce SiH₄, O₂ and Ar gas as starting gases into an HDP reactor and to produce a high-density plasma (>10¹⁶ ions/m³) in the reactor in a known manner. During the deposition of the SiO₂ layer on the bottom of the depression, however, part of the growing layer is sputtered away again by the ions of the plasma, principally the Ar ions. It is assumed that the deposition of SiO₂ on the side walls of the depression is based for by far the most part on the redeposition of this already grown and sputtered-away SiO₂ material. The SiO₂ redeposited on the side walls can in turn also be removed again in part by the sputtering action of the ions.

It is assumed, on the one hand, that a certain sputtering action of inert gas ions or other ions of the plasma is necessary in order to maintain the SiO₂ growth process. The publication “Modeling of SiO₂ Deposition in High Density Plasma Reactors and Comparisons of Model Predictions with Experimental Measurements”, Journal of Vacuum Science and Technology A 16(2), March/April 1998, pages 544 et seq., by E. Meeks et al. (referred to as “Meeks” hereinafter), discloses a model of the chemical reactions that proceed during the deposition of SiO₂ in an HDP-CVD process. This model assumes that, in a main reaction route, firstly SiHₓ is added on the surface of the structure, where x denotes the numerals 2 and/or 3. Afterwards, the hydrogen ligands are partially oxidized, so that the surface molecule SiG(OH)H₂ is produced, where G denotes an oxygen atom common to two of the surface molecules. This surface molecule is chemically inert, so that further SiHₓ molecules cannot be added to it. Bombardment of ions from the plasma, in particular Ar ions, results in chemical activation, so that addition of further SiHx molecules can take place. This main reaction route is joined by diverse secondary reaction routes and restructuring processes which lead to the final formation of SiO₂ in the region of the surface.

Following this assumption, U.S. Pat. No. 6,030,881 (Novellus Systems and IBM) describes an HDP deposition method of SiO₂ for filling depressions with a high aspect ratio, wherein an alternating sequence of two method steps with a different deposition/sputtering ratio is used. Consequently, a method step with a high deposition rate and a low sputtering rate is used first, in order to fill the depression with SiO₂ to an extent such that its side walls have already almost grown together at its upper edge as a result of the redeposition effect described. Afterward, the second method step is used, which has a low deposition rate and a high sputtering rate, in order primarily that the SiO₂ redeposited on the side walls is at least partly removed again. For carrying out the second method step, it is possible, for example, to increase the supply of argon. Afterward, the first method step can be used again, in order to fill the depression further. The two method steps are carried out successively as often as required until the depression has been filled in a manner free from voids. However, since the SiO₂ deposited on the bottom of the depression is also partly removed again through the second method step, this method is relatively laborious and cost-intensive.

According to U.S. Pat. No. 5,872,058 (Novellus Systems), by contrast, the intention is to suppress the sputtering effects in such an HDP deposition process, if possible, by drastically reducing the proportion of the inert gas in the total flow of the process gases into the reactor. Whereas the argon flow rate amounted to 30-60% of the total flow rate of the reaction gases in the case of the HDP processes known up to then, it is proposed to limit the argon flow rate to 0-13% of the total flow rate. Accordingly, it is thus the case, in particular, that an Ar-free process is also deemed to be a practicable possibility. In this case as well, however, the deposition process continues to be influenced by sputtering effects due to O₂ ions present in the plasma, which is also pointed out explicitly in the patent document.

### SUMMARY OF THE INVENTION

It is accordingly an object of the invention to provide a method of filling substrate depressions with SiO₂ which overcomes the above-mentioned disadvantages of the heretofore-known devices and methods of this general type and which provides for a method of filling depressions that can be used to fill even depressions with a high aspect ratio without leading to the formation of voids.

With the foregoing and other objects in view there is provided, in accordance with the invention, a method of filling a depression in a substrate, which comprises:

placing a substrate formed with a depression in a reactor chamber;

introducing a first silicon-containing reaction gas and one or more further reaction gases containing at least one material selected from the group consisting of H₂O₂ and H₂O into the reaction chamber containing the substrate; and

carrying out a chemical vapor deposition in a high-density-plasma process to thereby fill the depression in the substrate with SiO₂.

In accordance with an added feature of the invention, the plasma density is set to above 10¹⁶ ions/m³, preferably within the range from 10¹⁶ to 10²² ions/m³, and in particular from 10¹⁷ to 10¹⁹ ions/m³.

The invention first assumes that sputtering effects are not necessary, in principle, during the HDP vapor phase deposition for the layer growth of SiO₂, and that, accordingly, in particular with the aim of preventing the redeposition of sputtered-away SiO₂ on the side walls of a depression that is to be filled with SiO₂, such sputtering effects should be reduced further, if possible.

As was ascertained in the above-mentioned U.S. Pat. No. 5,872,058, sputtering effects due to the O₂ ions are still present in an Ar-free process as well.

An important aspect of the invention lies in replacing O₂ as oxygen-supplying reaction gas in an HDP deposition process at least partially by another oxygen-containing reaction gas, namely H₂O₂ and/or H₂O, and feeding this reaction gas to the HDP reaction chamber, so that the formation of O₂ ions can be reduced. According to the invention, then, the oxygen precursor O₂ is replaced by the oxygen precursor H₂O₂ and/or H₂O.

This can go so far that the reaction gas O₂ is completely replaced by H₂O₂ and/or H₂O, wherein case either only H₂O₂ or only H₂O or a mixture of these two reaction gases is formed in the reaction chamber. However, it is possible for O₂ still to be present in part and to be replaced by H₂O₂ and/or H₂O in the other part, so that one variant consists in forming a reaction gas mixture of O₂, H₂O₂ and H₂O in the reaction chamber.

The reaction chamber is always fed a first silicon-containing reaction gas, which may be formed by silane (SiH₄), for example.

Part of the method according to the invention is, moreover, that an HDP (high-density plasma) vapor phase deposition is carried out. This method is known per se in the prior art. Reference is had, for more detailed information, for example, to German published patent application DE 199 04 311 A1 (see also, U.S. Pat. No. 6,348,421), which is hereby incorporated into the disclosure content of the present application. Accordingly, an HDP reactor for producing a high-density plasma comprises a central chamber wherein semiconductor or insulator substrates are seated on a boat, which does not impair the substrates or introduce any contaminants into the substrates. The central chamber is composed of a material which can withstand pressures of around 1 mtorr or less, outgases to a minimal extent at such pressures and does not give rise to contaminants which penetrate into the interior of the chamber or into the substrates or into a thin film situated thereon. The central chamber operates at an operating pressure which is very much lower than in customary chambers for chemical vapor deposition or plasma-enhanced chemical vapor deposition. The pressure within the chamber is preferably about 5 mtorr, while a pressure of about 2 torr is typically used during plasma-enhanced chemical vapor deposition (PECVD). The plasma density within the chamber is much higher than during normal chemical vapor deposition, even if it is plasma-enhanced, and preferably lies above 10¹⁶ ions/m³, preferably in the range from 10¹⁶ to 10²² and in particular in the range from 10¹⁷ to 10¹⁹ ions/m³. However, the plasma density could also be even higher. In comparison with this, at the typical operating pressure of a chamber for plasma-enhanced chemical vapor deposition (PECVD), the plasma density lies in the range from 10¹⁴ to 10¹⁶ ions/m³. In the case of the method according to the invention, the HDP deposition can be carried out for example at pressures of approximately 1-20 mtorr and the substrate temperature can be regulated in a range between 200° C.-750° C., preferably 600° C.-750° C.

It is expected that the sputtering rate can be lowered again by approximately 50% in comparison with the Ar-free process. After a complete substitution of O₂, all that remains is the sputtering action of the SiHₓ⁺ ions.

For the case where, in accordance with the Meeks model described in the introduction, sputtering effects to a specific, albeit small, extent are necessary for the SiO₂ layer growth, it may also be provided that, as in the previously known methods, an inert gas such as argon or helium is fed in small quantities to the reaction chamber.

If desired, it is also possible additionally to provide passivating substances or atomic and/or molecular particles which can passivate the surface of the structure temporarily against addition of the filling material and/or a precursor of the filling material. This is based on the insight that, during the vapor phase deposition of the filling material, such a passivation can temporarily occur which can be eliminated again by bombardment with ions from the plasma. Hydrogen (H₂), for example, can be fed as a passivation gas to the reaction chamber.

As has already been described in the above-mentioned DE 199 04 311 A1, it is furthermore possible to provide an additional carbon doping of the SiO₂ filling introduced into the depression, in order to attain lower relative permittivities. For this purpose, a carbon-containing reaction gas, in particular one or more reaction gases from the group methane, tetraethyl orthosilicate (TEOS), methyltrimethoxysilane (MTMS) or phenyltrimethoxysilane (PTMS), can be used as first or further reaction gas.

A further optional measure relates, in particular, to processes such as the STI fabrication process already mentioned, wherein the substrate wafer does not have to be cooled from the rear side. The wafer temperature during these processes is produced by heating from the plasma and the ion current to the wafer, that is to say as a function of the pressure, the coupled-in power (HF and LF) and the partial pressures of the inflowing gases, on the one hand, and by cooling via radiation and cooling by the underlying chuck, on the other hand. In the case of the STI process, a temperature range of approximately 500-650° C. can be opened up here. It can be observed in the case of parameter changes, however, that the filling behavior is further improved as the temperature rises, i.e. it is desirable to provide a process temperature even higher than 650° C. This can be achieved, in accordance with a concomitant feature of the invention, with an electrically heated chuck which can be brought to temperatures in excess of 650° C. by way of a ceramic heating element, for example.

Other features which are considered as characteristic for the invention are set forth in the appended claims.

Although the invention is illustrated and described herein as embodied in a method of filling substrate depressions with SiO₂ by HDP vapor phase deposition with participation of H₂O₂ or H₂O as reaction gas, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a partial sectional view illustrating an intermediate stage in the filling of a substrate depression; and

FIG. 2 is a similar view of an end stage in the filling of the substrate depression.

### DESCRIPTION OF THE PREFERRED EMBODIMENTS

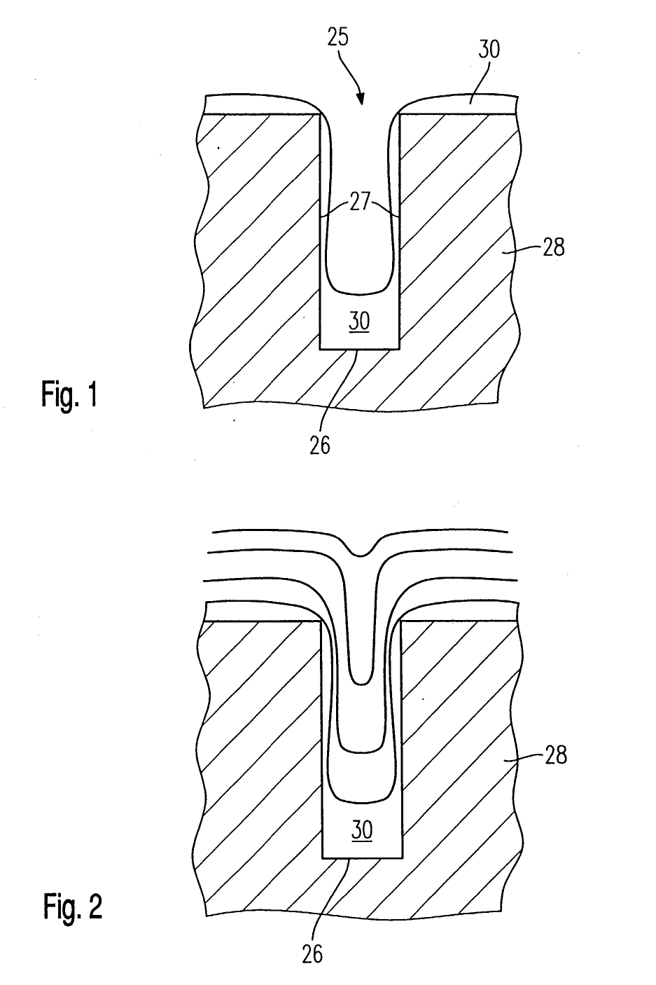

Referring now to the figures of the drawing in detail and first, particularly, to FIG. 1 thereof, there is shown a substrate 28 with a trench 25 which extends perpendicularly to the plane of the figure. The trench 25 may be, for example, for an STI insulation region between adjacent memory cells formed in the substrate 28. The trench 25, which has an aspect ratio of approximately 4, has already been partly filled from the bottom 26 with SiO₂ filling material 30. The silicon oxide SiO₂ 30 has also been deposited on the sidewalls 27 of the trench 25. Furthermore, deposition of SiO₂ 30 has also taken place outside the trench 25.

With reference to FIG. 2, the process according to the invention described herein largely avoids any sputtering effects. On account of the fact that the sputtering effects are largely suppressed by means of the method according to the invention, the redeposition of the SiO₂ on the side walls can be reduced in such a way that the depression 25 can be filled in a manner free from pocket voids.

I claim:

1. A method of filling a depression in a substrate, which comprises:
placing a substrate formed with a depression in a reactor chamber;
introducing a first silicon-containing reaction gas and one or more further reaction gases containing at least one material selected from the group consisting of H₂O₂ and H₂O into the reaction chamber containing the substrate; and
carrying out a chemical vapor deposition in a high-density-plasma process to thereby fill the depression in the substrate with SiO₂.

2. The method according to claim 1, which comprises adjusting the plasma density to above 10¹⁶ ions/m³.

3. The method according to claim 2, wherein the plasma density lies in a range from 10¹⁶ to 10²² ions/m³.

4. The method according to claim 3, wherein the plasma density lies in a range from 10¹⁷ to 10¹⁹ ions/m³.

5. The method according to claim 1, which comprises using O₂ as a further reaction gas.

6. The method according to claim 5, which comprises using a mixture of H₂O₂, H₂O, and O₂ as one of the further reaction gases.

7. The method according to claim 1, which comprises using an inert gas as a further reaction gas.

8. The method according to claim 7, wherein the inert gas is selected from the group consisting of Ar and He.

9. The method according to claim 1, wherein the first silicon-containing reaction gas is silane.

10. The method according to claim 1, wherein a carbon-containing reaction gas is used as the first or further reaction gas.

11. The method according to claim 1, wherein the carbon-containing reaction gas is one or more gases selected from the group consisting of methane, tetraethyl orthosilicate, methyltrimethoxysilane, and phenyltrimethoxysilane.

12. The method according to claim 1, which comprises using a passivation gas as a further reaction gas.

13. The method according to claim 1, wherein the passivation gas is hydrogen.

14. The method according to claim 1, which comprises heating the substrate with a heating source during the deposition.

15. The method according to claim 14, wherein the heating source is an electrically heated chuck.
